(19) United States
(12) Patent Application Publication
(10) Pub. No.: US 2025/0033295 A1
(43) Pub. Date: Jan. 30, 2025

(54) METHOD FOR PRODUCING STRUCTURE AND METHOD FOR PRODUCING ELECTRONIC COMPONENT DEVICE

(71) Applicant: Resonac Corporation, Tokyo (JP)

(72) Inventors: Takeshi SAITO, Tokyo (JP); Kazuya KAMIMURA, Tokyo (JP); Xin JIANG, Tokyo (JP)

(21) Appl. No.: 18/778,266

(22) Filed: Jul. 19, 2024

(30) Foreign Application Priority Data
Jul. 26, 2023 (JP) 2023-122038

(51) Int. Cl. B29C 65/48; B29C 65/00; B29C 65/50

(52) U.S. Cl. CPC B29C 65/4835; B29C 65/5057; B29C 66/73751; B29C 66/7394

(57) ABSTRACT

A method for producing a structure, the structure including a support member and a cured product of a thermosetting resin composition disposed at one face of the support member, the method including: disposing a thermosetting resin composition at both faces of the support member; curing the thermosetting resin composition; and removing a cured product of the thermosetting resin composition disposed at another face of the support member.

### CROSS-REFERENCE TO RELATED APPLICATION

This application is based on and claims priority under 35 USC 119 from Japanese Patent Application No. 2023-122038 filed on Jul. 26, 2023, the disclosure of which is incorporated by reference herein.

### BACKGROUND

### Technical Field

The present disclosure relates to a method for producing a structure and a method for producing an electronic component device.

### Background Art

A technique for producing an electronic component device referred to as wafer level packaging (WLP) has been attracting attention in recent times (see, for example, Japanese Application Laid-Open (JP-A) No. 2020-17717).

In the process of wafer level packaging, individuation of a wafer is performed after the completion of packaging, rather than cutting a wafer to the size of individual electronic components prior to the packaging.

In a typical method for producing electronic component devices, the circumference of electronic components disposed at a support member, such as a silicon substrate, is sealed with a sealant that includes a thermosetting resin. Specifically, a sealing portion is formed around the electronic components disposed at a support member by heating the sealant to cure a thermosetting resin included therein. In this process, the volume of the sealing portion, formed of a cured product of a sealant, shrinks owing to the action of a curing reaction of the thermosetting resin and the action of cooling from a heated state. The shrinkage in volume of the sealant may cause warpage of the support member.

When the sealing process is performed while a support member has a large area, such as a case of performing wafer level packaging, warpage of the support member caused by the shrinkage in volume of the sealant is more likely to occur. The warpage of the support member may affect the precision of subsequent processes, such as individuation of the wafer.

### SUMMARY

In view of the foregoing, an embodiment of the present disclosure aims to provide a method for producing a structure, and a method for producing an electronic component device, in which warpage of a support member due to shrinkage in volume of a thermosetting resin is suppressed.

The means for solving the problem includes the following embodiments.

<1> A method for producing a structure, the structure including a support member and a cured product of a thermosetting resin composition disposed at one face of the support member, the method including:
disposing a thermosetting resin composition at both faces of the support member;
curing the thermosetting resin composition; and
removing a cured product of the thermosetting resin composition disposed at another face of the support member.

<2> The method for producing a structure according to <1>, wherein a volume shrinkage rate after curing of the thermosetting resin composition disposed at the one face of the support member is from 80% to 120%, with respect to a volume shrinkage rate after curing of the thermosetting resin composition disposed at the other face of the support member.

<3> The method for producing a structure according to <1> or <2>, wherein the thermosetting resin composition is disposed at each of the faces of the support member as a layer.

<4> The method for producing a structure according to any one of <1> to <3>, wherein an area of a region at which the thermosetting resin composition is disposed, at the one face of the support member, is from 80% to 120% with respect to an area of a region at which the thermosetting resin composition is disposed, at the other face of the support member.

<5> The method for producing a structure according to any one of <1> to <4>, further including, before or after removing the cured product of the thermosetting resin composition, cutting the support member.

<6> A method for producing an electronic component device, the electronic component device including a support member, an electronic component disposed at one face of the support member, and a cured product of a thermosetting resin composition disposed around the electronic component, the method including:
disposing a thermosetting resin composition at the one face of the support member at which the electronic component is disposed, and at an opposite face from the one face of the support member at which the electronic component is disposed, respectively;
curing the thermosetting resin composition; and
removing a cured product of the thermosetting resin composition disposed at the opposite face of the support member from the one face at which the electronic component is disposed.

<7> The method for producing an electronic component device according to <6>, wherein a volume shrinkage rate after curing of the thermosetting resin composition, disposed at the one face of the support member at which the electronic component is disposed, is from 80% to 120% with respect to a volume shrinkage rate after curing of the thermosetting resin composition, disposed at the opposite face of the support member from the one face at which the electronic component is disposed.

<8> The method for producing an electronic component device according to <6> or <7>, wherein the thermosetting resin composition is disposed at each of the faces of the support member as a layer.

<9> The method for producing an electronic component device according to any one of <6> to <8>, wherein an area of a region at which the thermosetting resin composition is disposed, at the one face of the support member at which the electronic component is disposed, is from 80% to 120% with respect to an area of a region at which the thermosetting resin composition is disposed, at the opposite face of the support member from the one face at which the electronic component is disposed.

<10> The method for producing an electronic component device according to any one of <6> to <9>, wherein the thermosetting resin composition disposed around the electronic component is a sealant.

<11> The method for producing an electronic component device according to <10>, wherein the thermosetting resin composition disposed at the opposite face of the support member from the one face at which the electronic component is disposed is a sealant.

<12> The method for producing an electronic component device according to any one of <6> to <11>, further including, before or after removing a cured product of the thermosetting resin composition, cutting the support member.

According to an embodiment of the present disclosure, it is possible to provide a method for producing a structure, and a method for producing an electronic component device, in which warpage of a support member due to shrinkage in volume of a thermosetting resin is suppressed.

### DETAILED DESCRIPTION

In the present disclosure, the term “process” includes not only an independent process, but also a process that cannot be clearly distinguished from another process as long as the intended purpose of the process is achieved.

In the present disclosure, a numerical range indicated by using “to” means a range in which the numerical values described before and after “to” are included as a minimum value and a maximum value, respectively.

In numerical ranges described in the present disclosure in a stepwise manner, an upper limit value or a lower limit value described in a certain numerical range may be replaced with an upper limit value or a lower limit value of another numerical range described in a stepwise manner. In the numerical ranges described in the present disclosure, an upper limit value or a lower limit value described in a certain numerical range may be replaced with a value indicated in the examples.

In the present disclosure, each component may include plural kinds of substances corresponding to the component. In a case in which plural kinds of substances corresponding to each component are present in a composition, the content ratio or content of each component refers to the total content ratio or content of the plural kinds of substances present in the composition, unless otherwise specified.

In the present disclosure, particles corresponding to each component may include plural kinds of particles. In a case in which plural kinds of particles corresponding to each component are present in a composition, the particle size of each component refers to the value of the particle size of a mixture of the plural kinds of particles present in the composition, unless otherwise specified.

### <Method for Producing Structure>

An embodiment of the present disclosure is a method for producing a structure, the structure including a support member and a cured product of a thermosetting resin composition disposed at one face of the support member, the method including:
disposing a thermosetting resin composition at both faces of the support member;
curing the thermosetting resin composition; and
removing a cured product of the thermosetting resin composition disposed at another face of the support member.

In the method of the present embodiment, the thermosetting resin is cured under the condition that the thermosetting resin composition is disposed at both faces of the support member. Therefore, the volume shrinkage of the thermosetting resin, included in the thermosetting resin composition, is caused at both faces of the support member. As a result, a phenomenon of causing the support member to bend toward either one of the faces is less likely to occur as compared with a case in which the thermosetting resin is cured under the condition that the thermosetting resin composition is disposed at either one of the faces of the support member. Accordingly, it is possible to obtain a structure in which warpage of the support member is suppressed.

Further, in the method of the present embodiment, it is possible to suppress warpage of the support member by way of disposing the thermosetting resin composition at both faces thereof, rather than adjusting the components or the amount thereof in the thermosetting resin composition. Therefore, for example, the method is applicable to the production of a structure in which warpage of the support member is suppressed, even if the thermosetting resin composition used therein has a high degree of volume shrinkage rate and a tendency to cause warpage of the support member.

In the method of the present embodiment, the method of disposing the thermosetting resin composition at both faces of the support member is not particularly limited, and may be selected from known methods such as compression molding, injection molding or application. It is possible to attach the sheet-shaped thermosetting resin composition to the support member directly or via a release layer.

The thermosetting resin composition may be disposed simultaneously or sequentially at each of the faces of the support member.

From the viewpoint of suppressing warpage of the support member, the volume shrinkage rate after curing of the thermosetting resin composition disposed at the one face of the support member is preferably from 80% to 120%, more preferably from 90% to 110%, further preferably from 95% to 105%, with respect to the volume shrinkage rate after curing of the thermosetting resin composition disposed at the other face of the support member.

The volume shrinkage rate after curing of the thermosetting resin composition disposed at the one face of the support member is particularly preferably 100% with respect to the volume shrinkage rate after curing of the thermosetting resin composition disposed at the other face of the support member, i.e., the volume shrinkage rate after curing of the thermosetting resin composition disposed at the one face of the support member is equal to the volume shrinkage rate after curing of the thermosetting resin composition disposed at the other face of the support member.

In the method of the present embodiment, the volume shrinkage rate (VSR) of the thermosetting resin composition is measured by a method including the following steps (1) to (3).
(1) prepare a specimen formed of a cured product of the thermosetting resin composition by transfer molding using a mold with a size of 127 mm in length, 6.4 mm in height and 12.7 mm in width measured at room temperature (25° C.).
(2) remove the specimen from the mold immediately after the preparation, cool down to room temperature (25° C.), and measure the size of the specimen with a slide gauge. The measurement is performed on two specimens (specimen 1 and specimen 2) prepared under the same conditions.
(3) calculate the volume shrinkage rate (%) by the following formula from the size of the specimen measured at room temperature and the size of the mold measured at room temperature. In the formula, D₁ represents a size in length of the mold used for the preparation of specimen 1 (mm), d₁ represents a size in length of specimen 1 (mm), D₂ represents a size in length of the mold used for the preparation of specimen 2 (mm), and d₂ represents a size in length of specimen 2 (mm).

$$VSR ( \% ) = \frac{1}{2} ( \frac{{D}_{1} - {d}_{1}}{{D}_{1}} + \frac{{D}_{2} - {d}_{2}}{{D}_{2}} ) \times 100$$

From the viewpoint of suppressing warpage of the support member, the thermosetting resin composition is preferably disposed at each of the faces of the support member as a layer. When the thermosetting resin composition disposed at each of the faces of the support member is in the form of a layer, the thickness of the one layer is preferably from 80% to 120%, more preferably from 90% to 110%, further preferably from 95% to 105%, with respect to the thickness of the other layer.

The thickness of the one layer is preferably 100% with respect to the thickness of the other layer, i.e., the thickness of the one layer is equal to the thickness of the other layer.

When the thickness of the thermosetting resin composition in the form of a layer is not uniform, the maximum value of the thickness preferably satisfies the foregoing conditions.

From the viewpoint of suppressing warpage of the support member, the area of a region at which the thermosetting resin composition is disposed, at the one face of the support member, is preferably from 80% to 120%, more preferably from 90% to 110%, further preferably from 95% to 105%, with respect to the area of a region at which the thermosetting resin composition is disposed, at the other face of the support member.

The area of a region at which the thermosetting resin composition is disposed, at the one face of the support member, is particularly preferably 100% with respect to the area of a region at which the thermosetting resin composition is disposed, at the other face of the support member, i.e., the area of a region at which the thermosetting resin composition is disposed, at the one face of the support member, is equal to the area of a region at which the thermosetting resin composition is disposed, at the other face of the support member.

The method for curing the thermosetting resin composition disposed at both faces of the support member is not particularly limited, and may be selected according to the type of the thermosetting resin or the like.

For example, the thermosetting resin composition may be cured by heating the same to a temperature at which a cured reaction of the thermosetting resin included in the thermosetting resin composition is caused.

The method for removing the cured product of the thermosetting resin composition disposed at the one face of the support member is not particularly limited, and examples thereof include a method in which the cured product of the thermosetting resin composition is removed with a grinder or the like; a method in which the cured product of the thermosetting resin composition is removed with a chemical product or the like; and a method in which the cured product of the thermosetting resin composition is removed by separating a release layer, which is disposed between the cured product of the thermosetting resin composition and the support member, from the support member.

The method of the present disclosure may include a process other than the processes as described above, as necessary.

For example, the method may include a process of cutting the support member before or after removing the cured product of the thermosetting resin composition disposed at the one face of the support member. From the viewpoint of operation efficiency, the process of cutting the support member is preferably performed after removing the cured product of the thermosetting resin composition disposed at the one face of the support member.

The method for cutting the support member is not particularly limited. For example, the cutting may be performed with a dicing saw used for cutting a wafer during a process of producing electronic component devices.

### (Thermosetting Resin Composition)

The thermosetting resin composition used in the method as described above is a composition that at least includes a thermosetting resin.

The thermosetting resin composition may include a thermosetting resin alone or in combination with other components.

The type of the thermosetting resin is not particularly limited. For example, the thermosetting resin may be selected from epoxy resin, phenol resin, urea resin, melamine resin, unsaturated polyester resin, urethane resin, silicone resin and maleimide resin. In an embodiment, the thermosetting resin may be epoxy resin.

The thermosetting resin, included in the thermosetting resin composition disposed at the one face of the support member, may be the same with or different from the thermosetting resin included in the thermosetting resin composition disposed at the other face of the support member.

From the viewpoint of suppressing warpage of the support member, the thermosetting resin, included in the thermosetting resin composition disposed at the one face of the support member, is preferably the same with the thermosetting resin included in the thermosetting resin composition disposed at the other face of the support member.

The thermosetting resin composition may include a component other than the thermosetting resin.

Examples of the component other than the thermosetting resin include a filler, a curing agent, a curing accelerator, a coupling agent, an ion exchanger, a releasing agent, a fire retardant, and a colorant.

### (Support Member)

The type of the support member used in the method as described above is not particularly limited, and may be selected according to the purpose of the structure.

For example, the support member may be formed of an inorganic material such as silicon, metal or carbon, an organic material such as resin, or a composite of an inorganic material and an organic material.

In an embodiment, the support member may be a wafer. In the present disclosure, a wafer refers to a disk-shaped object used as a material for electronic component devices.

In the method of the present disclosure, warpage of the support member caused by volume shrinkage of the thermosetting resin composition is effectively suppressed even when the support member has a large area. Accordingly, the area of the support member used in the method of the present embodiment may be 25 cm² or more, 100 cm² or more, or 300 cm² or more. The area of the support member may be 3000 cm² or less, 2000 cm² or less, or 1000 cm² or less.

In the method of the present disclosure, warpage of the support member caused by volume shrinkage of the thermosetting resin composition is effectively suppressed even when the support member has a small thickness. Accordingly, the thickness of the support member used in the method of the present embodiment may be 5000 μm or less, 3000 μm or less, or 1000 μm or less. The thickness of the support member used in the method of the present embodiment may be 10 μm or more, 50 μm or more, or 100 μm or more.

In the production of the structure, a material other than the support member and the thermosetting resin composition may be used.

For example, when the structure is used as an electronic component device, an electronic component may be used in the production of the structure.

The structure including an electronic component may be produced by, for example, disposing the thermosetting resin composition at both faces of the support member, the support member having an electronic component disposed at one of the faces thereof; curing the thermosetting resin composition; and removing the cured product of the thermosetting resin composition disposed at the face of the support member at which the electronic component is not disposed.

The purpose of the structure produced by the method of the present disclosure is not particularly limited. For example, the structure including an electronic component may be used as an electronic component device.

### <Method for Producing Electronic Component Device>

An embodiment of the present disclosure is a method for producing an electronic component device, the electronic component device including a support member, an electronic component disposed at one face of the support member, and a cured product of a thermosetting resin composition disposed around the electronic component, the method including:
disposing a thermosetting resin composition at the one face of the support member at which the electronic component is disposed, and at an opposite face from the one face of the support member at which the electronic component is disposed, respectively;
curing the thermosetting resin composition; and
removing a cured product of the thermosetting resin composition disposed at the opposite face of the support member from the one face at which the electronic component is disposed.

In the method of the present embodiment, the thermosetting resin is cured under the condition that the thermosetting resin composition is disposed at both faces of the support member. Therefore, the volume shrinkage of the thermosetting resin, included in the thermosetting resin composition, is caused at both faces of the support member. As a result, a phenomenon of causing the support member to bend toward either one of the faces is less likely to occur as compared with a case in which the thermosetting resin is cured under the condition that the thermosetting resin composition is disposed at either one of the faces of the support member. Accordingly, it is possible to obtain an electronic component device in which warpage of the support member is suppressed.

Further, in the method of the present embodiment, it is possible to suppress warpage of the support member by way of disposing the thermosetting resin composition at both faces thereof, rather than adjusting the components or the amount thereof in the thermosetting resin composition. Therefore, for example, the method is applicable to the production of an electronic component device in which warpage of the support member is suppressed, even if the thermosetting resin composition used therein has a high degree of volume shrinkage rate and a tendency to cause warpage of the support member.

In the method of the present embodiment, the method of disposing the thermosetting resin composition at both faces of the support member is not particularly limited, and may be selected from known methods such as compression molding, injection molding or application. It is possible to attach the sheet-shaped thermosetting resin composition to the support member directly or via a release layer.

The thermosetting resin composition may be disposed simultaneously or sequentially at each of the faces of the support member.

From the viewpoint of suppressing warpage of the support member, the volume shrinkage rate after curing of the thermosetting resin composition disposed at the one face of the support member at which the electronic component is disposed is preferably from 80% to 120%, more preferably from 90% to 110%, further preferably from 95% to 105%, with respect to the volume shrinkage rate after curing of the thermosetting resin composition disposed at the opposite face of the support member from the one face at which the electronic component is disposed.

The volume shrinkage rate after curing of the thermosetting resin composition disposed at the one face of the support member at which the electronic component is disposed is particularly preferably 100% with respect to the volume shrinkage rate after curing of the thermosetting resin composition disposed at the opposite face of the support member from the one face at which the electronic component is disposed, i.e., the volume shrinkage rate after curing of the thermosetting resin composition disposed at the one face of the support member at which the electronic component is disposed is equal to the volume shrinkage rate after curing of the thermosetting resin composition disposed at the opposite face of the support member from the one face at which the electronic component is disposed.

From the viewpoint of suppressing warpage of the support member, the thermosetting resin composition is preferably disposed at each of the faces of the support member as a layer. When the thermosetting resin composition disposed at each of the faces of the support member is in the form of a layer, the thickness of the layer disposed at the one face of the support member at which the electronic component is disposed is preferably from 80% to 120%, more preferably from 90% to 110%, further preferably from 95% to 105%, with respect to the thickness of the layer disposed at the opposite face of the support member from the one face at which the electronic component is disposed.

The thickness of the layer disposed at the one face of the support member at which the electronic component is disposed is particularly preferably 100% with respect to the thickness of the layer disposed at the opposite face of the support member from the one face at which the electronic component is disposed, i.e., the thickness of the layer disposed at the one face of the support member at which the electronic component is disposed is equal to the thickness of the layer disposed at the opposite face of the support member from the one face at which the electronic component is disposed.

When the thickness of the thermosetting resin composition in the form of a layer is not uniform, the maximum value of the thickness preferably satisfies the foregoing conditions.

From the viewpoint of suppressing warpage of the support member, the area of a region at which the thermosetting resin composition is disposed, at the one face of the support member at which the electronic component is disposed, is preferably from 80% to 120%, more preferably from 90% to 110%, further preferably from 95% to 105%, with respect to the area of a region at which the thermosetting resin composition is disposed, at the opposite face of the support member from the one face at which the electronic component is disposed.

The area of a region at which the thermosetting resin composition is disposed, at the one face of the support member at which the electronic component is disposed, is preferably 100% with respect to the area of a region at which the thermosetting resin composition is disposed, at the opposite face of the support member from the one face at which the electronic component is disposed, i.e., the area of a region at which the thermosetting resin composition is disposed, at the one face of the support member at which the electronic component is disposed, is equal to the area of a region at which the thermosetting resin composition is disposed, at the opposite face of the support member from the one face at which the electronic component is disposed.

The method for curing the thermosetting resin composition disposed at both faces of the support member is not particularly limited, and may be selected according to the type of the thermosetting resin or the like.

For example, the thermosetting resin composition may be cured by heating the same to a temperature at which a cured reaction of the thermosetting resin included in the thermosetting resin composition is caused.

The method for removing the cured product of the thermosetting resin composition disposed at the opposite face of the support member from the one face at which the electronic component is disposed is not particularly limited, and examples thereof include a method in which the cured product of the thermosetting resin composition is removed with a grinder or the like; a method in which the cured product of the thermosetting resin composition is removed with a chemical product or the like; and a method in which the cured product of the thermosetting resin composition is removed by separating a release layer, which is disposed between the cured product of the thermosetting resin composition and the support member, from the support member.

The method of the present disclosure may include a process other than the processes as described above, as necessary.

For example, the method may include a process of cutting the support member before or after removing the cured product of the thermosetting resin composition disposed at the opposite face of the support member from the one face at which the electronic component is disposed. From the viewpoint of operation efficiency, the process of cutting the support member is preferably performed after removing the cured product of the thermosetting resin composition disposed at the opposite face of the support member from the one face at which the electronic component is disposed.

The method for cutting the support member is not particularly limited. For example, the cutting may be performed with a dicing saw used for cutting a wafer during a process of producing electronic component devices.

As for the details and preferred embodiments of the thermosetting resin composition and the support member used in the method of the present embodiment, reference can be made to the details and preferred embodiments of the thermosetting resin composition and the support member used in the method for producing a structure as mentioned above.

The thermosetting resin composition used in the method of the present embodiment may be a sealant. The sealant is disposed around the electronic component (including a space between the electronic component and the support member) and serves to protect the electronic component, for example. The sealant may be solid or liquid at ordinary temperature (25° C.).

Examples of the sealant include those at least including an epoxy resin and a curing agent as a resin component, and an inorganic filler such as silica or alumina.

The content of the resin component in the sealant may be from 10% by volume to 70% by volume, from 15% by volume to 60% by volume, or from 20% by volume to 50% by volume, with respect to the total volume of the sealant, for example.

The content of the inorganic filler in the sealant may be from 30% by volume to 90% by volume, from 40% by volume to 85% by volume, or from 50% by volume to 80% by volume, with respect to the total volume of the sealant, for example.

The sealant may further include a component such as a curing accelerator, a coupling agent, an ion exchanger, a releasing agent, a fire retardant, and a colorant.

All publications, patent applications, and technical standards mentioned in the present specification are incorporated herein by reference to the same extent as if each individual publication, patent application, or technical standard was specifically and individually indicated to be incorporated by reference.

What is claimed is:

1. A method for producing a structure, the structure comprising a support member and a cured product of a thermosetting resin composition disposed at one face of the support member, the method comprising:
disposing a thermosetting resin composition at both faces of the support member;
curing the thermosetting resin composition; and
removing a cured product of the thermosetting resin composition disposed at another face of the support member.

2. The method for producing a structure according to claim 1, wherein a volume shrinkage rate after curing of the thermosetting resin composition disposed at the one face of the support member is from 80% to 120%, with respect to a volume shrinkage rate after curing of the thermosetting resin composition disposed at the other face of the support member.

3. The method for producing a structure according to claim 1, wherein the thermosetting resin composition is disposed at each of the faces of the support member as a layer.

4. The method for producing a structure according to claim 1, wherein an area of a region at which the thermosetting resin composition is disposed, at the one face of the support member, is from 80% to 120% with respect to an area of a region at which the thermosetting resin composition is disposed, at the other face of the support member.

5. The method for producing a structure according to claim 1, further comprising, before or after removing the cured product of the thermosetting resin composition, cutting the support member.

6. A method for producing an electronic component device, the electronic component device comprising a support member, an electronic component disposed at one face of the support member, and a cured product of a thermosetting resin composition disposed around the electronic component, the method comprising:
disposing a thermosetting resin composition at the one face of the support member at which the electronic component is disposed, and at an opposite face from the one face of the support member at which the electronic component is disposed, respectively;
curing the thermosetting resin composition; and
removing a cured product of the thermosetting resin composition disposed at the opposite face of the support member from the one face at which the electronic component is disposed.

7. The method for producing an electronic component device according to claim 6, wherein a volume shrinkage rate after curing of the thermosetting resin composition, disposed at the one face of the support member at which the electronic component is disposed, is from 80% to 120% with respect to a volume shrinkage rate after curing of the thermosetting resin composition, disposed at the opposite face of the support member from the one face at which the electronic component is disposed.

8. The method for producing an electronic component device according to claim 6, wherein the thermosetting resin composition is disposed at each of the faces of the support member as a layer.

9. The method for producing an electronic component device according to claim 6, wherein an area of a region at which the thermosetting resin composition is disposed, at the one face of the support member at which the electronic component is disposed, is from 80% to 120% with respect to an area of a region at which the thermosetting resin composition is disposed, at the opposite face of the support member from the one face at which the electronic component is disposed.

10. The method for producing an electronic component device according to claim 6, wherein the thermosetting resin composition disposed around the electronic component is a sealant.

11. The method for producing an electronic component device according to claim 10, wherein the thermosetting resin composition disposed at the opposite face of the support member from the one face at which the electronic component is disposed is a sealant.

12. The method for producing an electronic component device according to claim 6, further comprising, before or after removing a cured product of the thermosetting resin composition, cutting the support member.
